(19) United States
(12) Patent Application Publication
(10) Pub. No.: US 2023/0221726 A1
(43) Pub. Date: Jul. 13, 2023

(54) METHOD FOR THE QUALIFICATION OF A CONTROL WITH THE AID OF A CLOSED-LOOP SIMULATION PROCESS

(71) Applicant: Robert Bosch GmbH, Stuttgart (DE)

(72) Inventors: Joachim Sohns, Ludwigsburg (DE); Patrick Weber, Rutesheim (DE)

(21) Appl. No.: 18/063,368

(22) Filed: Dec. 8, 2022

(30) Foreign Application Priority Data
Jan. 10, 2022 (DE) 10 2022 200 158.3

(51) Int. Cl. G05D 1/02

(52) U.S. Cl. CPC G05D 1/0214; G05D 1/0272

(57) ABSTRACT

A computer-implemented method for comparing generated data sequences for an at least semi-automated driving of a mobile platform, which were generated with the aid of a closed-loop simulation process, and a recorded data sequence of a trip of the mobile platform, controlled in at least semi-automated fashion, for the qualification of the control. The method includes: providing the recorded data sequence, which is based on a multiplicity of determinants, of trips of the mobile platform controlled in at least semi-automated fashion; providing a multitude of generated data sequences, which are based on the multiplicity of determinants, of simulated trips, which were generated with the aid of the closed-loop simulation process; providing similarity limits and a similarity metric for the respective determinant; comparing the recorded data sequence to each individual generated data sequence of the multitude of recorded data sequences.

### CROSS REFERENCE

The present application claims the benefit under 35 U.S.C. § 119 of German Patent Application No. DE 10 2022 200 158.3 filed on Jan. 10, 2022, which is expressly incorporated herein by reference in its entirety.

### FIELD

The present invention relates to a computer-implemented method for comparing data sequences, which were generated with the aid of a closed-loop simulation process, and a recorded data sequence of a trip of a mobile platform controlled in at least semi-automated fashion.

### BACKGROUND INFORMATION

The virtual validation and release of new technologies is regarded as one of the greatest challenges of simulation technology. This is particularly true in the case of the development of HAD (Highly Automated Driving) systems in autonomous or automated driving. For modern autonomous pilot systems, it is estimated that as of automation level 3, a resource expenditure of 80% lies in the validation and only 20% in the development, since the safeguarding of the systems is very complex. In the area of highly automated driving (HAD), simulations are used, among other things, to recreate critical situations which have arisen in vehicle measurements.

### SUMMARY

For a qualification of a control of a mobile platform, a well-founded method is lacking which makes it possible to computationally ascertain uncertain models for a simulated control. Without such a foundation, it is scarcely possible to carry out downstream evaluations for the qualification and/or validation.

This especially holds true for a simulation in a closed loop, since in that case, only boundary conditions such as lane markings or road users are able to be specified exactly, but not a desired behavior of the “agents” which determine the control in the closed loop. As soon as a simulation or an experimental trial of the control is started, the agent travels through the world including boundary conditions and “experiences” time-variable closed-loop signals at its system inputs. It thus generates its closed-loop behavior at the system outputs. These signals represent the actual trial or the simulation and, as compared to the open loop, cannot be influenced directly.

For the qualification and/or validation of a closed-loop simulation, it is thus not sufficient if only the critical behavior of a vehicle is recreated in the simulation. The operative closed-loop states in the simulation must also be sufficiently like the reality, that is, in the case of the correspondingly controlled trips of the vehicle.

According to aspects of the present invention, provided are a computer-implemented method for comparing generated data sequences for an at least semi-automated driving of a mobile platform, which were generated with the aid of a closed-loop simulation process, and a recorded data sequence of a trip of the mobile platform controlled in at least semi-automated fashion; a utilization of the computer-implemented method; a computer program; and a computer-readable storage medium. Advantageous refinements and example embodiments of the present invention are disclosed herein.

In this entire description of the present invention, the sequence of method steps is presented so that the method is easily comprehensible. However, one skilled in the art will recognize that many of the method steps may also be run through in a different sequence and lead to the same or an equivalent result. With this in mind, the sequence of the method steps may be changed accordingly. Some features are provided with numerals in order to improve the readability or to make the assignment clearer, but this does not imply a presence of certain features.

According to one aspect of the present invention, a computer-implemented method is provided for comparing generated data sequences for an at least semi-automated driving of a mobile platform, which were generated utilizing a closed-loop simulation process, and a recorded data sequence of a trip of the mobile platform, controlled in at least semi-automated fashion, for the qualification of the control. According to an example embodiment of the present invention, the computer-implemented method includes the following steps:
Providing the recorded data sequence, which is based on a multiplicity of determinants, of trips of the mobile platform controlled in at least semi-automated fashion;
Providing a multitude of generated data sequences, which are based on the multiplicity of determinants, of simulated trips, which were generated utilizing the closed-loop simulation process;
Providing similarity limits and a similarity metric for the respective determinant;
Comparing the recorded data sequence to each individual generated data sequence of the multitude of recorded data sequences, by:
Determining a similarity of initial values of at least one determinant of the recorded data sequence to the determinant of each generated data sequence of the multitude of generated data sequences with the aid of the respective similarity limits;
Determining a similarity of the time characteristic of the at least one determinant of the recorded data sequence to the determinant of each generated data sequence of the multitude of generated data sequences with the aid of the respective similarity metric and the respective similarity limits; the recorded data sequence being categorized as a function of the determined similarity of the initial values of the at least one determinant and the determined similarity of the time characteristic of the at least one determinant, into a first evaluation class for determining a further determinant for a qualification of the control and/or being categorized into a second evaluation class for determining highly sensitive behavior of the control, in order to qualify the control of the at least semi-automated mobile platform by use of the computer-implemented method.

In other words, using the computer-implemented method, it is possible to determine the extent to which the closed-loop simulation process simulates trips of the mobile platform controlled in at least semi-automated fashion, in order, for example, to qualify the closed-loop simulation process as test means for an at least semi-automated mobile platform.

In this context, according to an example embodiment of the present invention, a number and/or a multitude of determinants, the at least one determinant, may be selected, which together characterize and define a model for the at least semi-automated platform and/or an initial condition for a scenario to be analyzed with the computer-implemented method and/or the scenario to be analyzed and/or fixed parameters and/or free parameters. In particular, with the determinants selected in each case in relation to an initial condition, a similarity of the road for the mobile platform and/or an initial distance to a preceding vehicle and/or absolute or relative speeds of the participant mobile platforms and or a scene and/or a complete trip of another mobile platform and many other variables and/or states and/or parameters for describing the scenario, may be featured. A complete trip of another mobile platform belongs to the determinants particularly when it is not controlled by semi-automation, but its maneuvering is described in P and it behaves like a dynamic boundary condition.

In this context, the control method, which is embedded into the closed-loop simulation process, may be like the control method of the control unit that is used by the at least semi-automated mobile platform for the recorded data sequence.

According to an example embodiment of the present invention, the generated data sequences may be generated by a simulator, that is, with the aid of a simulation process. Selected determinants may be provided for the simulation process, which include the respective starting conditions and boundary conditions like, namely, parameters, especially for the utilized model of the mobile platform, such as, e.g., particular parameters for a special model for a brake of the mobile platform. These selected determinants may be assigned to the respective generated data sequences, and particularly to the recorded data sequences.

In addition, the determinants feature test intervals, including maximum and minimum values, particularly for the starting and boundary conditions, as well as parameters, e.g., for describing a scenario.

For instance, according to an example embodiment of the present invention, for an initial speed of the mobile platform, the similarity metric may include a difference of a speed of the mobile platform of a generated data sequence compared to a recorded data sequence. According to one boundary condition, a further example may relate to a maximum width of a traffic lane (traffic-lane boundary condition), to which limit values for a similarity may also be assigned. Such a limit value may indicate the instantaneous deviation as of which a generated data sequence is still regarded as sufficiently similar relative to a recorded data sequence. The respective determinants may be assigned both to the generated data sequences and to the recorded data sequences, so that in terms of the simulation process and the trip of the mobile platform controlled in at least semi-automated fashion, the determinants match sufficiently exactly within predetermined limits.

In this connection, a deviation dP, thus, a deviation of the determinants, such as of starting conditions, of a simulation sP compared to a vehicle road testing vP may be a function MP(sP,vP) of a similarity measure of the respective determinants.

The respective determinants sP and vP, which may also be vector quantities, may have initial properties for the analysis utilizing the simulation process and are directly adjustable or parameterizable and, since model parameters are also included, may be regarded as part of a scenario for the analysis.

Examples for such determinants sP and vP may be: A speed of an ego vehicle, like the mobile platform, at the beginning of a data sequence and/or a length of an interruption of a lane marking (lane error) and/or an average y-noise of a lane marking (lateral noise).

During the generation of data sequences by the simulation process, it may be assumed that an autonomous agent, not able to be influenced directly, has driven through a scenario in autonomous driving mode with the aid of autonomously controlling vehicle software.

This agent reacts to changed determinants sP, like starting conditions and/or boundary conditions and/or parameters, in the scenario of the simulation and may be described with system states sX(t) and output variable sY(t). In this context, one or more system states sX(t), which may be linked functionally in correspondence with a function of the system states according to f(X(t); t), may also be output variables of the simulation process. These system states sX(t) and output variables sY(t) cannot be influenced directly and only manifest after running through the simulation process according to generated data sequences S.

Similarity limits TX between a system state of a mobile platform vX(t) and a system state of simulation process sX(t) may be defined and made available, as well as a calculation rule or a similarity metric for determining a similarity of a time characteristic of a determinant, such as between two curves.

According to an example embodiment of the present invention, a state difference dX of determinants that are variable as a function time, such as states vX(t) und sX(t), for example, may be determined utilizing a similarity metric. For instance, an average and/or maximum speed difference between the generated data sequences and the recorded data sequences may be determined.

In addition, according to an example embodiment of the present invention, agents may be defined for the simulation process which control mobile platforms in the environment of the mobile platform considered and are defined via corresponding determinants.

In particular, generated data sequences S and recorded data sequences V may have a typical time duration of, e.g., 5 s to 10 s, which corresponds to a time duration of a scenario considered, such as a passing maneuver, for example.

Notably, generated data sequences S and/or recorded data sequences V may be produced from larger generated data sequences S_large (endurance simulations) and recorded data sequences V_large (endurance runs/endurance vehicle road testing) by cutting out corresponding sequences.

The computer-implemented method described thus compares a complete trip of a mobile platform, controlled in at least semi-automated fashion, to a simulated closed-loop trip, in order to qualify the control of the at least semi-automated mobile platform. That is, the computer-implemented method presented relates to the SIL (software in the loop) simulation. The method may also be used on HIL (hardware in the loop) and VIL (vehicle in the loop) closed-loop methods. Although in the case of the technologies from SIL via HIL to VIL, in each case correspondingly fewer parts are modeled in the simulation loop and more portions of the mobile platform to be tested are used.

In other words, the computer-implemented method presented is able to efficiently and continuously support a qualification and/or validation of an SIL (or HIL, or VIL) simulation environment, while at the same time the simulation process may be used in the computer-implemented method for the development and release of an at least semi-automated mobile platform and/or autonomous vehicles such as aircraft and/or robots.

The computer-implemented method may solve a central problem of a qualification of a control of a mobile platform with the aid of a simulation process, in which a tool validation, such as the simulation process itself and/or models used and/or middleware used, is coupled to the qualification and/or validation of the simulation process and must run concurrently during the development project of the control for the mobile platform.

In particular, a requirement for such a computer-implemented method is that in the continuous development of a control for an at least semi-automated driving of a mobile platform, new scenarios are simulated over and over again for trips for which the simulation environment, that is, the simulation process, is not yet well-proven.

To that end, as explained more precisely below, during the development process of the control, the computer-implemented method predetermines a work sequence from which the next steps in each instance in a tool validation may be obtained.

In particular, new trips of the mobile platform, controlled in at least semi-automated fashion, may be provided with the computer-implemented method and/or new run-throughs of the simulation process may be provided, as well as expansion of a data analysis utilizing additional determinants such as parameters and/or state variables.

In addition, utilizing the computer-implemented method, it is possible to determine scenarios and ranges of parameter values in which a control of the at least semi-automated mobile platform is able to be tested based on simulation, and scenarios and ranges of parameter values for which the simulation process is not yet usable and may possibly be improved.

Furthermore, using the computer-implemented method, as explained further below, a reason may be ascertained as to why the simulation process is not yet usable in certain ranges of determinants.

Scenarios for the comparison of generated data sequences from the closed-loop simulation process and recorded data sequences from trips of the mobile platform, controlled in at least semi-automated fashion, may be defined utilizing a multiplicity of determinants. Specifically, they may include:
A list of fixed starting and boundary conditions which are not to be changed. These invariants may define the main features of the scenario and separate it from other scenarios like, for example, a number of 3 lanes and/or cornering and/or no oncoming traffic.
A list of the starting and boundary conditions which are to be analyzed and varied in the scenario such as, e.g., a length of an interruption of a lane marking and/or a y-noise of the lane marking and/or a speed of the ego mobile platform.

Specifically, in this context, it is possible to determine more precisely:
A span or interval for an analysis with these boundary conditions and/or limit values for a similarity between the recorded data sequences of trips of the mobile platform, and the data sequences generated from the simulation process using these boundary conditions. Employing these variations, a range of parameter values for the scenarios may be defined and a space of the analysis may be spanned. From the quantity of variations, a possibly infinitely large quantity of candidates for potential further simulations is obtained. The goal is a valid simulation in as large a range as possible.
A list of output variables and system states which are to be evaluated for similarity in the time characteristic in the closed loop. In this context, with the aid of a calculation rule, output variables may be determined from multiple system states considered over time. Safety goals, which must be observed by certain determinants, may be output variables or a system state itself, but are always regarded as output variables.

In particular, similarity limits for a similarity of system states of the generated data sequences and the recorded data sequences may be defined for the scenarios.

In addition, similarity limits may be defined for a similarity of output variables and/or safety goals of the generated data sequences and the recorded data sequences.

Furthermore, limit values may be defined for a violation of safety goals and/or output variables corresponding to system states in the sense of an absolute value.

These characterizing variables, based on the generated data sequences and the recorded data sequences, may be determined in each case for a predetermined time interval such as, e.g., an average speed and/or statistical moment of the speed for characterizing noise and/or distances and/or safety metrics.

In particular, for example, a similarity may be determined with the aid of an arbitrary differential measure and/or distance measure, which assigns a scalar or vector difference or distance to two fingerprints. At the same time, this differential measure and/or distance measure may also be coupled to the specific concrete case of application. For instance, if in the driving situation, the intention is to assess how well an automated system is detecting or holding to the traffic lane, elements of a fingerprint which characterizes the traffic lane may be weighted, for example, with elements of a weighting matrix determined based on a real traffic lane and/or setpoint traffic lane.

In a further advantageous development of the present invention, a measure for the similarity is a function of a Hamming distance between the two fingerprints. The Hamming distance measures the number of bits in which the two fingerprints differ from each other. For example, the measure for the similarity may include an average value or median of the elements in an element-wise product of both fingerprints.

Fingerprint methods are characterized in that, with the aid of a coding process, they are able to transform higher-dimensional information such as snapshot aerial views of a traffic scene into a unique coding, e.g., a 64-bit number, and transform it back again. Certain intermediate steps, particularly the initial discretization of the high-dimensional data, of these methods additionally used to form distances between the high-dimensional information coupled with a metric. One thus obtains a unique coding of both original sequences and a differential measure.

A similarity measure, that is, a similarity metric, may be evaluated over a time curve, like, for example, with the aid of squares of error of a course of a curve. Employing similarity metrics, a similarity may be determined between a generated data sequence and a recorded data sequence, particularly in terms of a determinant. The associated determinants such as, e.g., system states or a subset of these system states, may span a space within which the similarity evaluation is carried out. For each pair-wise comparison, a recorded data sequence of a vehicle measurement including the associated system states may be used as reference, and a difference may be formed with respect to all available data sequences generated from a simulation process.

Alternatively or additionally, the roles of the simulation data and the vehicle data may be exchanged. In this case, all time segments from the vehicle data are compared in each case to a time segment from the simulation, and the classification is subsequently carried out like in the main variant. Instead of new vehicle data, in this case new simulation data are utilized.

In this variant, the parameter space is spanned by the system states from the simulation.

Alternatively or additionally, instead of vehicle measurements, data may be used which were generated with other reference systems such as, e.g., hardware-in-the-loop and/or another software-in-the-loop system and/or vehicle-in-the-loop.

Alternatively or in addition to subdividing the simulation data and reference data into sections of equal length, the division into subsections may also be carried out in another manner.

In particular, the computer-implemented method may be used to evaluate functions that are not safety-critical. In this application case, instead of criticality metrics, requirements that are imposed on software functions are evaluated.

According to one aspect of the present invention, the recorded data sequence is categorized as a function of the determined similarity of the initial values of a multiplicity of selected determinants and the determined similarity of the time characteristic of the multiplicity of selected determinants. A scenario to be analyzed may be characterized more precisely by the computer-implemented method by use of a multiplicity of selected determinants.

According to one aspect of the present invention, the computer-implemented method is provided for a multitude of recorded data sequences, and the method is carried out for each of the multitude of recorded data sequences.

According to one aspect of the present invention, the computer-implemented method is carried out for a multitude of recorded data sequences, and the respective recorded data sequence is categorized with the first evaluation class or with the second evaluation class.

A closed-loop simulation process may be assessed as qualified if, for a sufficient number of simulated driving situations, thus, generated data sequences, known reference driving situations, thus, recorded data sequences, are able to be discovered which as a result evolve exactly like the scenario simulated in each case; probability is then high that the reality is portrayed sufficiently accurately by the simulation process.

According to one aspect of the present invention, the recorded data sequence of the multitude of recorded data sequences is categorized into a first evaluation class if, for all generated data sequences whose initial values for each of a number of selected determinants are within the respective similarity limit, the similarity of the time characteristic for each of the number of selected determinants is outside of the respective similarity limits.

Alternatively or additionally, the recorded data sequence of the multitude of recorded data sequences may be categorized into a second evaluation class if, for all generated data sequences whose initial values for each of the number of selected determinants are within the respective similarity limit, the similarity of the time characteristic for at least one determinant of the number of selected determinants is within the respective similarity limits and if the similarity of the time characteristic for at least one determinant of the number of selected determinants is outside of the respective similarity limits.

Alternatively or additionally, the recorded data sequence of the multitude of recorded data sequences may be categorized into a third evaluation class if, for all generated data sequences whose initial values for each of a number of selected determinants are within the respective similarity limit, the similarity of the time characteristic for each of the number of selected determinants is within the respective similarity limits.

Preferably, the closed-loop simulation process may be evaluated as simulating the recorded data sequence of the trip of the mobile platform, controlled in at least semi-automated fashion, sufficiently accurately for a qualification, if the respective recorded data sequence is categorized into the third evaluation class.

According to one aspect of the present invention, the recorded data sequence of the multitude of recorded data sequences is categorized into a fourth evaluation class if all initial values for each of the number of selected determinants are determined outside of the respective similarity limits.

Since in this case, the initial conditions lie outside of the respective similarity limits, with such recorded data sequences, an attempt may be made to repeat the comparison with the computer-implemented method, using a different selection of determinants which define the specific scenario.

According to one aspect of the present invention, the closed-loop simulation process simulates trips of the mobile platform, controlled in at least semi-automated fashion, sufficiently accurately for a qualification if the multitude of the recorded data sequences are categorized in the third evaluation class.

Since in the third evaluation class, the recorded data sequences lie within the similarity limits for the initial conditions and the time characteristic, the results of the simulation process agree here with the results of the trips of the mobile platform within the similarity limits defined and provided.

According to one aspect of the present invention, the closed-loop simulation process simulates trips of the mobile platform, controlled in at least semi-automated fashion, sufficiently accurately for a qualification if the multitude of recorded data sequences are categorized in the third evaluation class or the fourth evaluation class.

Since in the fourth evaluation class, the initial conditions of the scenario of the simulation do not agree with the initial conditions of the trips of the mobile platform, recorded data sequences which are categorized into the fourth evaluation class are not relevant for a qualification of the simulation process.

According to one aspect, the computer-implemented method described above is repeated if the recorded data sequence was classified with the second evaluation class, and in this instance, the similarity limits provided have narrower limits for determining the similarity of the initial values of at least one determinant of the recorded data sequence to the determinant of each generated data sequence of the multitude of generated data sequences, in order to compare the evaluation class of the repetition of the computer-implemented method to the evaluation class of a previous implementation of the computer-implemented method.

By limiting the similarity, with a new classification as described above, an attempt may be made for the respective recorded data sequence to agree sufficiently accurately in comparison to all generated data sequences, so as to be classified into the third evaluation class. To that end, a candidate list may be provided which lists determinants whose similarity limits may be defined more narrowly.

According to one aspect of the present invention, one of the computer-implemented methods described above is repeated with a further determinant for the recorded data sequence and the generated data sequences if the recorded data sequence is categorized with the first evaluation class and/or the second evaluation class; the further determinant is supplied with the aid of a candidate list for further determinants, in order to compare the evaluation class of the repetition to the evaluation class of a previous implementation of the method.

By adding a further determinant, the simulation process may possibly be carried out based on a sufficient amount of relevant determinants as necessary for a correct simulation of the trip of the mobile platform characterized by the recorded data sequence. To that end, a candidate list may be provided which lists suitable further determinants in order to carry out the method.

According to one aspect of the present invention, if the evaluation class of the repetition of the method is the same as the evaluation class of the previous implementation of the method, and the recorded data sequence is classified with the second evaluation class, at least one new recorded data sequence of a trip of the mobile platform, controlled in at least semi-automated fashion, is required, whose selected determinants correspond to the classified recorded data sequence, in order to examine a multistability of the control method.

Since in this case, outcomes which match with varying degree result from the comparison of the recorded data sequence to the generated data sequences, this may also mean for the control of the mobile platform that in such a scenario, the control is multistable. Since according to this computer-implemented method, these outcomes matching with varying degree result in the repetition with a further determinant, as well, it may be recommended to check the control with further trips of the mobile platform.

According to one aspect of the present invention, if the evaluation class of the repetition is the same as the evaluation class of the previous implementation of the method, it is determined whether one of the determinants of the generated sequences exceeds a safety-related value.

For some safety-related output variables of trips of the mobile platform and simulations, safety limit values sTYsafety, vTYsafety like, e.g., a prohibited exceeding of certain speeds may be predetermined both for the simulation process and for the trips of the mobile platform.

The safety limit values sTYsafety and vTYsafety may be calculated with a suitable metric for time signals of output variable Y(t), but are not a differential measure between sTYsafety und vTYsafety, rather are compared in each case to an external specification like, e.g., maximum speed of the vehicle. This may be relevant particularly for recorded data sequences which are categorized into the first evaluation class, because recorded data sequences of the first evaluation class, which thus are categorized into the first evaluation class, cannot be represented correctly by the simulation process based on the determinants selected. Thus, by the comparison to the safety limit values, it may be determined whether at least one of the determinants, which is not correctly simulated, is safety-related. From the standpoint of the vehicle, false positive results are especially relevant in this instance.

False positive results signify an unsafe behavior and an exceeding of the vTY safety in the vehicle, accompanied by a safe behavior in the simulation without exceeding of the sTY safety. This information may be used to entirely prohibit the simulation as test means for parameter space P for safety reasons until causes have been discussed.

False negative results signify a safe behavior and no exceeding of the vTY safety in the vehicle, accompanied by unsafe behavior in the simulation with exceeding of the sTY safety. This result may be used to mark the simulation as inefficient for certain parameter ranges or entirely in P, since parameters in P are characterized wrongly as unsafe (false alarm).

According to an example embodiment of the present invention, utilization of one of the computer-implemented methods described above is provided for the qualification and/or verification of the control of the at least semi-automated mobile platform with the aid of the computer-implemented method.

Using the computer-implemented method as described above, advantageously both the simulation process may be qualified and the qualification of the control of the mobile platform may be carried out.

According to an example embodiment of the present invention, a computer program is provided which includes commands that, upon execution of the program by a computer, prompt it to carry out one of the computer-implemented methods described above.

With such a computer program, the method may easily be integrated into different systems.

According to an example embodiment of the present invention, a computer-readable storage medium is provided which includes commands that, upon execution by a computer, prompt it to carry out one of the computer-implemented methods described above.

With such a computer-readable storage medium, the method may be integrated into different systems.

### BRIEF DESCRIPTION OF THE DRAWINGS

Exemplary embodiments of the present invention are represented with reference to FIG. 1 and are explained in greater detail in the following.

FIG. 1 shows a data flow chart of the computer-implemented method for comparing generated data sequences and recorded data sequences, according to an example embodiment of the present invention.

### DETAILED DESCRIPTION OF EXAMPLE EMBODIMENTS

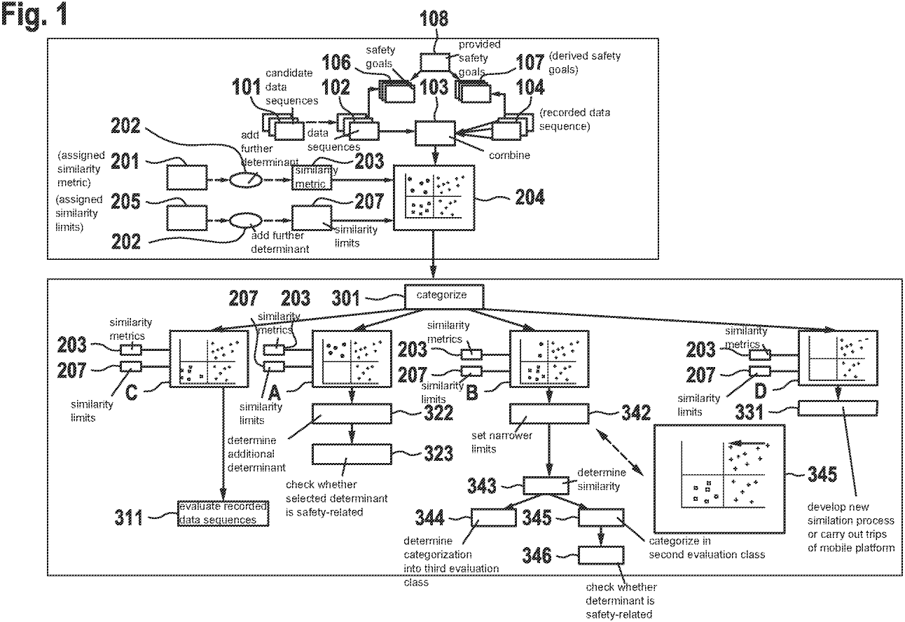

FIG. 1 shows schematically the computer-implemented method for comparing generated data sequences 102 for an at least semi-automated driving of a mobile platform, which were generated with the aid of a closed-loop simulation process, and a recorded data sequence 104 of a trip of the mobile platform, controlled in at least semi-automated fashion, for the qualification of the control of the mobile platform.

A multitude of data sequences 102, generated by a closed-loop simulation process, may be supplied from candidate data sequences 101 and combined with a multitude of supplied recorded data sequences 104 in a step 103, in order to compare them

Safety goals 106 may be derived for generated data sequences 102 from provided safety goals 108, and derived safety goals 107 may also be provided for recorded data sequences 104.

Based on provided similarity limits 207 and similarity metrics 203, in step 204, a similarity of initial values of at least one determinant of a recorded data sequence 104 to the determinant of each generated data sequence 102 of the multitude of generated data sequences may be determined with the aid of respective similarity limits 207.

Furthermore, in step 204, a similarity of the time characteristic of the at least one determinant of a recorded data sequence 104 to the determinant of each generated data sequence of the multitude of generated data sequences 102 is determined with the aid of the respective similarity metric and the respective similarity limits.

If in a step 202, a further determinant is to be added for the comparison, an assigned similarity metric 201 and assigned similarity limits 205 may be determined for a further determinant from a provided candidate list.

In this context, the box for step 204 in FIG. 1 sketches two-dimensionally on a horizontal axis, a difference of initial values dP of the corresponding determinants of the respective generated data sequence and the respective recorded data sequence, in order to represent a similarity of the initial values. Plotted on the vertical axis is a difference between a similarity metric and the respective similarity limits of a time characteristic of the at least one determinant of the respective generated data sequence and the respective recorded data sequence, in order to represent a similarity of the time characteristic.

Depending on the determined similarity of the initial values of the at least one determinant and the determined similarity of the time characteristic of the at least one determinant, in step 301, the recorded data sequence is categorized into a first evaluation class A and/or a second evaluation class B, in order to qualify the control of the mobile platform. In this context, with a recorded data sequence 104 which is categorized into first evaluation class A, a further determinant may be determined, and alternatively or additionally, with a recorded data sequence 104 which is categorized into second evaluation class B, a highly sensitive behavior of the control of the mobile platform may be determined.

In this context, recorded data sequence 104 of the multitude of recorded data sequences is categorized into first evaluation class A if, for all generated data sequences 102, their initial values for each of a number of selected determinants are within the respective similarity limit, and their similarity of the time characteristic for each of the number of selected determinants is outside of the respective similarity limits.

Recorded data sequence 104 of the multitude of recorded data sequences is categorized into second evaluation class B if, for all generated data sequences 102, their initial values for each of the number of selected determinants are within the respective similarity limit, and their similarity of the time characteristic for at least one determinant of the number of selected determinants is within the respective similarity limits and if their similarity of the time characteristic for the at least one determinant of the number of selected determinants is outside of the respective similarity limits.

Recorded data sequences 104 are categorized into a third evaluation class C if, for all generated data sequences 102, their initial values for each of a number of selected determinants are within the respective similarity limit, and if for all generated data sequences 102, their similarity of the time characteristic for each of the number of selected determinants is within the respective similarity limits.

Recorded data sequences 104 are categorized into a fourth evaluation class D if, for all generated data sequences 102, their initial values for each of a number of selected determinants are outside of the respective similarity limit.

In a step 311, recorded data sequences 104, which are categorized into third evaluation class C, may be evaluated with a robustness value in accordance with a number of generated data sequences 102 with which they are categorized into third evaluation class C. A generated data sequence 102 which has the least deviation from recorded data sequence 104 may be determined as proxy for the number of generated data sequences 102 that are categorized with recorded data sequence 104 into third evaluation class C.

Using an additional determinant, which may be determined with the aid of a candidate list for additional determinants in step 322, recorded data sequences 104 which are categorized into first evaluation class A may run through the computer-implemented method again with the additional determinant, starting with step 103, in order to be categorized again, because namely, the simulation process may be carried out in more detailed fashion with the additional determinant, permitting better simulation of recorded data sequence 104. The result may be that with the additional determinant, recorded data sequence 104 is categorized into third evaluation class C.

If recorded data sequence 104 with the additional determinant continues to be categorized into first evaluation class A, in step 323, with the aid of a comparison to safety-related values, it may be checked whether one of the determinants selected for the comparison of generated data sequence 102 and recorded data sequence 104 is safety-related.

For recorded data sequences 104 which are categorized into second evaluation class B, in a step 342, narrower limits may be set for the similarity limits provided for determining the similarity of the initial values of at least one determinant of recorded data sequence 104 to the determinant of each generated data sequence of the multitude of generated data sequences 102, so as to compare the evaluation class upon repeating the computer-implemented method, to the evaluation class of a previous implementation of the method. Such a shift of the x-axis is sketched in diagram 345, which results from the fact that recorded data sequence 104 is re-categorized in step 301.

Due to the narrower limits for determining the similarity of the initial values, in a step 343, it may be determined that for the multitude of generated data sequences with this recorded data sequence, a categorization 344 into third evaluation class C results.

If, in spite of the narrower limits for determining the similarity of the initial values, this recorded data sequence 104 continues to be categorized into second evaluation class B, in step 345, the computer-implemented method may be run through again with an additional determinant, beginning with step 204, in order to be categorized once again, because namely, the simulation process may be carried out in more detailed fashion with the additional determinant, permitting better simulation of recorded data sequence 104. The result may be that with the additional determinant, recorded data sequence 104 is categorized into third evaluation class C.

If with the additional determinant, recorded data sequence 104 continues to be categorized into second evaluation class B, in step 346, with the aid of a comparison to safety-related values, it may be checked whether one of the determinants selected for the comparison of generated data sequence 102 and recorded data sequence 104 is safety-related.

In the case of recorded data sequences 104 which are classified into fourth evaluation class D, none of the multitude of generated data sequences 102 is suitable for corresponding recorded data sequence 104, so that in a step 331, a new simulation process may be developed and carried out, or trips of the mobile platform corresponding to the selected determinants may be carried out.

For an overview as to the range in which the selected determinants, such as a range of parameters, for example, the computer-implemented method may be employed, the corresponding selected determinants of generated data sequences 102, which are classified with recorded data sequences 104 into third evaluation class C or fourth evaluation class D, may themselves be transferred directly into a parameter space.

Decisive in the transfer is the respective value of the corresponding determinant of the recorded data sequence vP of each one of the comparison (e.g.,V1 vs every Sx). In this connection, parameter points of third evaluation class C may be assigned to a domain A, and parameter points of fourth evaluation class D may be assigned to a domain C. Customary parameter-space methods such as kernel density estimation or classification may be used for this purpose.

For the parameter points of first evaluation class A and second evaluation class B, the methods described above may be carried out with narrower limits and/or additional determinants prior to the corresponding entering into the parameter space.

What is claimed is:

1. A computer-implemented method for comparing generated data sequences for an at least semi-automated driving of a mobile platform, which were generated utilizing a closed-loop simulation process, and a recorded data sequence of a trip of the mobile platform controlled in at least semi-automated fashion, for qualification of the control, the method comprising the following steps:
providing the recorded data sequence, which is based on a multiplicity of determinants, of trips of the mobile platform controlled in at least semi-automated fashion;
providing a multitude of generated data sequences of simulated trips which were generated utilizing the closed-loop simulation process, which are based on the multiplicity of determinants;
providing respective similarity limits and a respective similarity metric for each respective determinant;
comparing the recorded data sequence to each generated data sequence of the multitude of recorded data sequences, by:
determining a similarity of initial values of at least one determinant of the recorded data sequence to a determinant of the generated data sequence of the multitude of generated data sequences using the respective similarity limits,
determining a similarity of a time characteristic of the at least one determinant of the recorded data sequence to the determinant of each generated data sequence of the multitude of generated data sequences using the respective similarity metric and the respective similarity limits; and
depending on the determined similarity of the initial values of the at least one determinant and the determined similarity of the time characteristic of the at least one determinant, categorizing the recorded data sequence into a first evaluation class for determining a further determinant for a qualification of the control and/or categorizing the recorded data sequence into a second evaluation class for determining highly sensitive behavior of the control, to qualify the control of the at least semi-automated mobile platform using the computer-implemented method.

2. The computer-implemented method as recited in claim 1, wherein the recorded data sequence is categorized as a function of the determined similarity of the initial values of a multiplicity of selected determinants and the determined similarity of the time characteristic of the multiplicity of selected determinants.

3. The computer-implemented method as recited in claim 1, wherein a multitude of recorded data sequences is provided, and the method is carried out for each of the multitude of recorded data sequences.

4. The computer-implemented method as recited in claim 1, wherein the method is carried out for a multitude of recorded data sequences, and wherein each of the recorded data sequences is categorized into the first evaluation class or into the second evaluation class.

5. The computer-implemented method as recited in claim 4, wherein:
each recorded data sequence of the multitude of recorded data sequences is categorized into the first evaluation class when, for all generated data sequences, their initial values for each of a number of selected determinants are within the respective similarity limit, and their similarity of the time characteristic for each of the number of selected determinants is outside of the respective similarity limits; and/or
the recorded data sequence of the multitude of recorded data sequences is categorized into the second evaluation class when, for all generated data sequences, their initial values for each of the number of selected determinants are within the respective similarity limit and their similarity of the time characteristic for the at least one determinant of the number of selected determinants is within the respective similarity limits, and when their similarity of the time characteristic for at least one determinant of the number of selected determinants is outside of the respective similarity limits; and/or
the recorded data sequence of the multitude of recorded data sequences is categorized into a third evaluation class when, for all generated data sequences whose initial values for each of a number of selected determinants are within the respective similarity limit, their similarity of the time characteristic for each of the number of selected determinants is within the respective similarity limits.

6. The computer-implemented as recited in claim 5, wherein the closed-loop simulation process simulates the recorded data sequence of the trip of the mobile platform, controlled in at least semi-automated fashion, sufficiently accurately for a qualification when the recorded data sequence is categorized into the third evaluation class.

7. The computer-implemented method as recited in claim 5, wherein the recorded data sequence of the multitude of recorded data sequences is categorized into a fourth evaluation class when, for all generated data sequences, their initial values for each of the number of selected determinants are determined outside of the respective similarity limits.

8. The computer-implemented method as recited in claim 5, wherein the closed-loop simulation process simulates trips of the mobile platform, controlled in at least semi-automated fashion, sufficiently accurately for a qualification when the multitude of the recorded data sequences are categorized in the third evaluation class.

9. The computer-implemented method as recited in claim 7, wherein the closed-loop simulation process simulates trips of the mobile platform, controlled in at least semi-automated fashion, sufficiently accurately for a qualification when the multitude of recorded data sequences are categorized in the third evaluation class or the fourth evaluation class.

10. The computer-implemented method as recited in claim 1, wherein the steps of the method are repeated when the recorded data sequence was classified with the second evaluation class, and the similarity limits provided have narrower limits for determining the similarity of the initial values of at least one determinant of the recorded data sequence to the determinant of each generated data sequence of the multitude of generated data sequences, in order to compare the evaluation class of the repetition of the method to the evaluation class of a previous implementation of the method.

11. The computer-implemented method as recited in claim 1, wherein the steps of the method are repeated with a further determinant for the recorded data sequence and the generated data sequences when the recorded data sequence is categorized with the first evaluation class and/or the second evaluation class, the further determinant being supplied using a candidate list for further determinants, in order to compare the evaluation class of the repetition to the evaluation class of a previous implementation of the method.

12. The computer-implemented method as recited in claim 10, wherein when the evaluation class of the repetition of the method is the same as the evaluation class of the previous implementation of the method, and the recorded data sequence is classified with the second evaluation class, at least one new recorded data sequence of a trip of the mobile platform, controlled in at least semi-automated fashion, is required, whose selected determinants correspond to the classified recorded data sequence, in order to examine a multistability of the control method.

13. The computer-implemented method as recited in claim 10, wherein when the evaluation class of the repetition is the same as an evaluation class of the previous implementation of the method, it is determined whether one of the determinants of the generated data sequences exceeds a safety-related value.

14. The computer-implemented method as recited in claim 1, wherein the method is used for qualification and/or verification of the control of the at least semi-automated mobile platform.

15. A non-transitory computer-readable storage medium on which is stored a computer program for comparing generated data sequences for an at least semi-automated driving of a mobile platform, which were generated utilizing a closed-loop simulation process, and a recorded data sequence of a trip of the mobile platform controlled in at least semi-automated fashion, for qualification of the control, the computer program, when executed by a computer, causing the computer to perform the following steps:
providing the recorded data sequence, which is based on a multiplicity of determinants, of trips of the mobile platform controlled in at least semi-automated fashion;
providing a multitude of generated data sequences of simulated trips which were generated utilizing the closed-loop simulation process, which are based on the multiplicity of determinants;
providing respective similarity limits and a respective similarity metric for each respective determinant;
comparing the recorded data sequence to each generated data sequence of the multitude of recorded data sequences, by:
determining a similarity of initial values of at least one determinant of the recorded data sequence to a determinant of the generated data sequence of the multitude of generated data sequences using the respective similarity limits,
determining a similarity of a time characteristic of the at least one determinant of the recorded data sequence to the determinant of each generated data sequence of the multitude of generated data sequences using the respective similarity metric and the respective similarity limits; and
depending on the determined similarity of the initial values of the at least one determinant and the determined similarity of the time characteristic of the at least one determinant, categorizing the recorded data sequence into a first evaluation class for determining a further determinant for a qualification of the control and/or categorizing the recorded data sequence into a second evaluation class for determining highly sensitive behavior of the control, to qualify the control of the at least semi-automated mobile platform using the computer-implemented method.
